(19) United States
(12) Patent Application Publication
(10) Pub. No.: US 2011/0074015 A1
(43) Pub. Date: Mar. 31, 2011

(54) STACKED SEMICONDUCTOR DEVICE AND A METHOD FOR MANUFACTURING THE SAME

(75) Inventor: Kazumasa Suzuki, Chiba-ken (JP)

(73) Assignee: Kabushiki Kaisha Toshiba, Tokyo (JP)

(21) Appl. No.: 12/718,022

(22) Filed: Mar. 5, 2010

(30) Foreign Application Priority Data
Sep. 28, 2009 (JP) JP 2009-221980

(51) Int. Cl. H01L 23/498; H01L 21/60; H01L 23/28; H01L 21/56

(52) U.S. Cl. 257/737; 438/107; 257/E23.068; 257/E23.116; 257/E21.503; 257/E21.508

(57) ABSTRACT

An upper-side semiconductor chip is stacked on a lower-side semiconductor chip by connection through microbumps. In the lower-side semiconductor chip that forms a gap with the upper-side semiconductor chip to be filled with an underfill resin, and is sealed with a molding resin, a polyimide film is formed on the chip surface in a peripheral area excluding openings of bonding pads. A stacked semiconductor device and a method for manufacturing the stacked semiconductor device are provided that the device is capable of suppressing generation of a void in the underfill resin layer, prevents a decrease in measurement accuracy of the gap between the stacked semiconductor chips, and prevents peeling of the molding resin.

### CROSS-REFERENCE TO RELATED APPLICATIONS

This application is based upon and claims the benefit of priority from the prior Japanese Patent Application No. 2009-221980, filed on Sep. 28, 2009, the entire contents of which are incorporated herein by reference.

### FIELD

The invention relates to a stacked semiconductor device and a method for manufacturing the same.

### BACKGROUND

In order to respond to demands for higher function and higher performance of digital equipment, it is required to improve data transmission between a logic circuit and a memory circuit and to increase a memory capacity. A CoC (Chip on Chip)-system stacked semiconductor device, with a plurality of semiconductor chips stacked on one package, has been in practical use. When the stacked semiconductor chips are flip-chip bonded to each other through microbumps each having a diameter of about 30 μm, multipoint connection at about several thousands of points is possible, so as to attempt to expand a bus width and improve transmission speed.

In the case of performing flip-chip bonding through bumps such as microbumps, after the bumps are formed respectively in a lower-side semiconductor chip having bonding pads for external connection and an upper-side semiconductor chip, the bumps provided in the lower-side semiconductor chip and the bumps provided in the upper-side semiconductor chip are connected to each other. Subsequently, a gap between the upper and lower semiconductor chips is filled with an underfill resin. The bonding pads of the lower-side semiconductor chip are then wire-bonded. Finally, the whole of the stacked semiconductor chips are sealed with a molding resin. The above are disclosed in Japanese Patent Publication (Kokai) No. 2008-192815.

In the case of performing the sealing with the molding resin, since adhesion between the semiconductor chip and the molding resin is low, the molding resin may be peeled at a chip corner or the like when thermal stress is applied due to a difference in coefficient of thermal expansion between the semiconductor chip and the molding resin.

It is disclosed in Japanese Patent Publication (Kokai) No. 8-186109 that a polyimide film is formed on the surface of the semiconductor chip, thereby improving the adhesion to the molding resin.

However, when the polyimide film is formed on the whole surface of the lower-side semiconductor chip in the case of performing the flip-chip bonding through the microbumps, the gap between the upper and lower chips, which is originally narrow, becomes even narrower. This makes it difficult to uniformly fill the microbump area with the underfill resin at the time of filling with the underfill resin. When the filling with the underfill resin is non-uniform, a void is generated in the underfill resin layer. This causes a problem of destruction of a microbump due to thermal treatment or the like during package assembly.

Further, when the polyimide film is formed on the whole surface of the lower-side semiconductor chip, accurate measurement of the gap between the upper and lower semiconductor chips becomes difficult.

The invention provides a stacked semiconductor device and a method for manufacturing the stacked semiconductor device, the device being capable of suppressing generation of a void in an underfill resin layer and preventing a decrease in measurement accuracy of a gap between stacked semiconductor chips, while preventing peeling of a molding resin.

### SUMMARY

A first aspect of the invention may comprise a first semiconductor chip that has a first connection area formed with a first plurality of microbumps and a peripheral area formed with a plurality of bonding pads, a second semiconductor chip that has a second connection area formed with a second plurality of microbumps on a surface opposed to the first connection area, and is stacked on the first semiconductor chip with the first plurality of microbumps and the second plurality of microbumps connected to each other, an underfill resin filled in a gap between the first semiconductor chip and the second semiconductor chip, a molding resin sealing the first semiconductor chip and the second semiconductor chip and a film that has favorable adhesion to the molding resin formed on the chip surface in a region excluding openings of the bonding pads out of the peripheral area of the first semiconductor chip.

Further, another aspect of the invention may comprise the steps of forming a first plurality of microbumps in a first connection area, forming a plurality of bonding pads in a peripheral area, and forming a film with favorable adhesion to a molding resin on the chip surface in the peripheral region excluding openings of the bonding pads of a first semiconductor chip, forming a second plurality of microbumps in a second connection area of a second semiconductor chip, stacking the second semiconductor chip on the first semiconductor chip by making the first connection area and the second connection area opposed to each other and connecting the first plurality of microbumps with the second plurality of microbumps, filling a gap between the first semiconductor chip and the second semiconductor chip with an underfill resin and sealing the first semiconductor chip and the second semiconductor chip with the molding resin.

### DESCRIPTION OF DRAWINGS

The accompanying drawings, which are incorporated in and constitute a part of this specification, illustrate embodiments of the invention and together with the description, serve to explain the principles of the invention.

FIG. 1 is a schematic sectional view showing a constitutional example of a stacked semiconductor device according to a first embodiment of the invention.

FIG. 2 is a schematic plan view showing a constitutional example of a lower-side semiconductor chip in the stacked semiconductor device according to the first embodiment of the invention.

FIG. 3 is a schematic plan view showing a constitutional example of an upper-side semiconductor chip in the stacked semiconductor device according to the first embodiment of the invention.

FIG. 4 is a schematic plan view showing an another constitutional example of a lower-side semiconductor chip in the stacked semiconductor device according to the first embodiment of the invention.

FIG. 5 is a schematic plan view showing an another constitutional example of a lower-side semiconductor chip in the stacked semiconductor device according to the first embodiment of the invention.

FIG. 6 is a flowchart showing an example of a method for manufacturing the stacked semiconductor device according to the first embodiment of the invention.

FIG. 7 is a schematic sectional view for explaining a process for manufacturing the stacked semiconductor device according to the first embodiment of the invention.

FIG. 8 is a schematic sectional view for explaining a process for manufacturing the stacked semiconductor device according to the first embodiment of the invention.

FIG. 9 is a schematic sectional view for explaining a process for manufacturing the stacked semiconductor device according to the first embodiment of the invention.

FIG. 10 is a schematic plan view showing a constitutional example of a lower-side semiconductor chip in a stacked semiconductor device according to a second embodiment of the invention.

FIG. 11 is a schematic sectional view showing a state of filling with an underfill resin in the stacked semiconductor device according to the second embodiment of the invention.

FIG. 12 is a schematic sectional view showing a constitutional example of the stacked semiconductor device according to the second embodiment of the invention.

### DETAILED DESCRIPTION

Hereinafter, embodiments of the invention will be described with reference to the drawings. The same or corresponding parts in the drawings are attached with the same reference numerals, and explanations thereof are omitted.

### First Embodiment

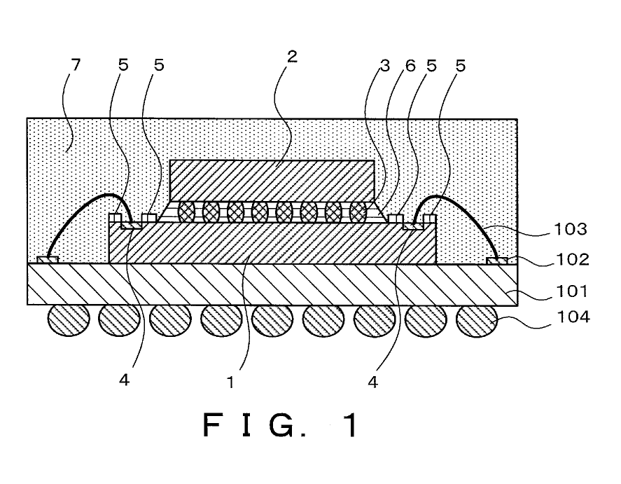

FIG. 1 is a schematic sectional view showing a constitutional example of a stacked semiconductor device according to the first embodiment of the invention.

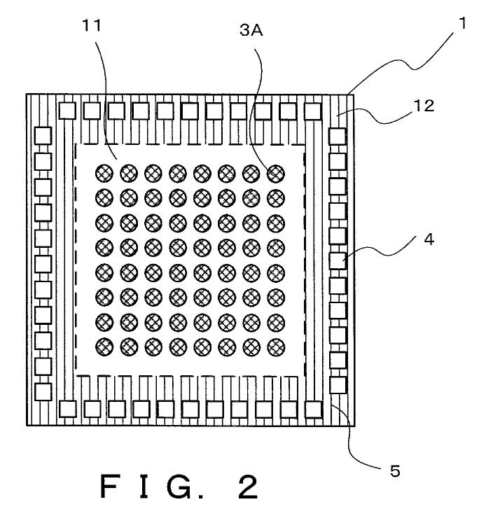

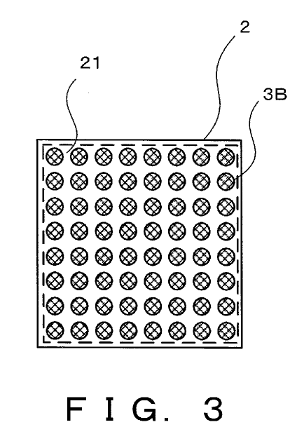

The stacked semiconductor device of the embodiment takes a structure of stacking an upper-side semiconductor chip 2 on a lower-side semiconductor chip 1 through microbumps 3. Here, FIGS. 2 and 3 respectively show constitutional examples of the lower-side semiconductor chip 1 and the upper-side semiconductor chip 2.

FIG. 2 is a schematic plan view showing a constitutional example of the lower-side semiconductor chip 1.

The lower-side semiconductor chip 1 has a connection area 11 formed with a plurality of microbumps 3A, and a peripheral area 12 formed with a plurality of bonding pads 4.

Here, what is characteristic of the lower-side semiconductor chip 1 of the embodiment is that a polyimide film is formed on the chip surface in an area excluding the connection area 11 and openings of the bonding pads 4 in the peripheral area 12.

FIG. 3 is a schematic plan view showing a constitutional example of the upper-side semiconductor chip 2.

The upper-side semiconductor chip 2 has a connection area 21 formed with a plurality of microbumps 3B on the surface opposed to the connection area 11 of the lower-side semiconductor chip 1 when it is stacked on the lower-side semiconductor chip 1.

When the upper-side semiconductor chip 2 is stacked on the lower-side semiconductor chip 1, the connection area 11 of the lower-side semiconductor chip 1 and the connection area 21 of the upper-side semiconductor chip 2 are opposed to each other, and the microbumps 3A of the lower-side semiconductor chip 1 and the microbumps 3B of the upper-side semiconductor chip 2 are connected to each other.

With this connection, the microbumps 3A and the microbumps 3B are unified, to form the microbumps 3 shown in FIG. 1.

Next, as shown in FIG. 1, the stacked semiconductor device of the embodiment where the upper-side semiconductor chip 2 is stacked on the lower-side semiconductor chip 1 through the microbumps 3 includes an underfill resin 6, with which a gap between the lower-side semiconductor chip 1 and the upper-side semiconductor chip 2 is filled and a molding resin 7 that seals the lower-side semiconductor chip 1 and the upper-side semiconductor chip 2.

Here, on the chip surface of the peripheral area 12 of the lower-side semiconductor chip 1 of the embodiment, the polyimide film 5 is formed in an area excluding the connection area 11 and the openings of the bonding pads 4. Therefore, there is no case where the chip surface of the lower-side semiconductor chip 1 comes into direct contact with the molding resin 7.

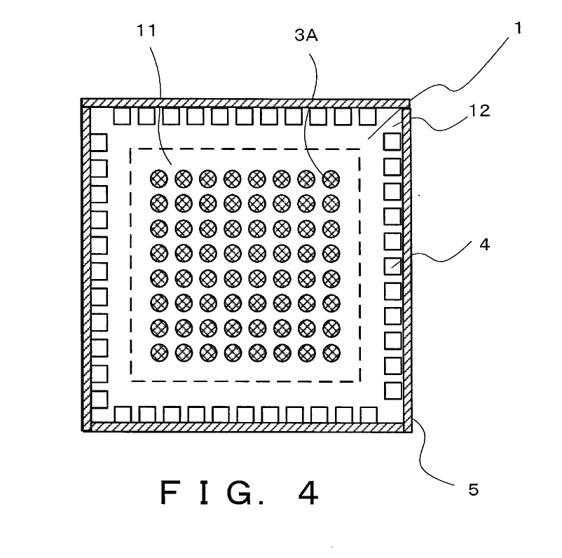

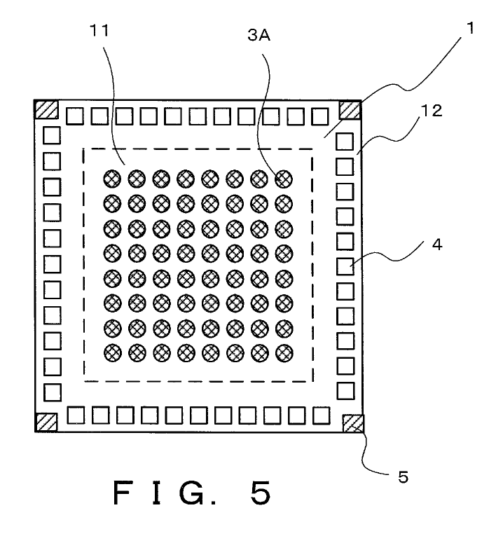

As shown in FIG. 4, it is possible to form the polyimide film 5 on a rim outside the bonding pad 4 of the lower-side semiconductor chip 1. Further, as shown in FIG. 5, it is also possible to form the polyimide film 5 only at least in corner sections of the lower-side semiconductor chip 1.

In the first embodiment shown in FIG. 1, the lower-side semiconductor chip 1 is connected to a wiring substrate 101, the bonding pad 4 of the lower-side semiconductor chip 1 is connected to a connecting pad 102 of the wiring substrate 101 through a bonding wire 103, and an external connection terminal 104 is formed on the wiring substrate 101.

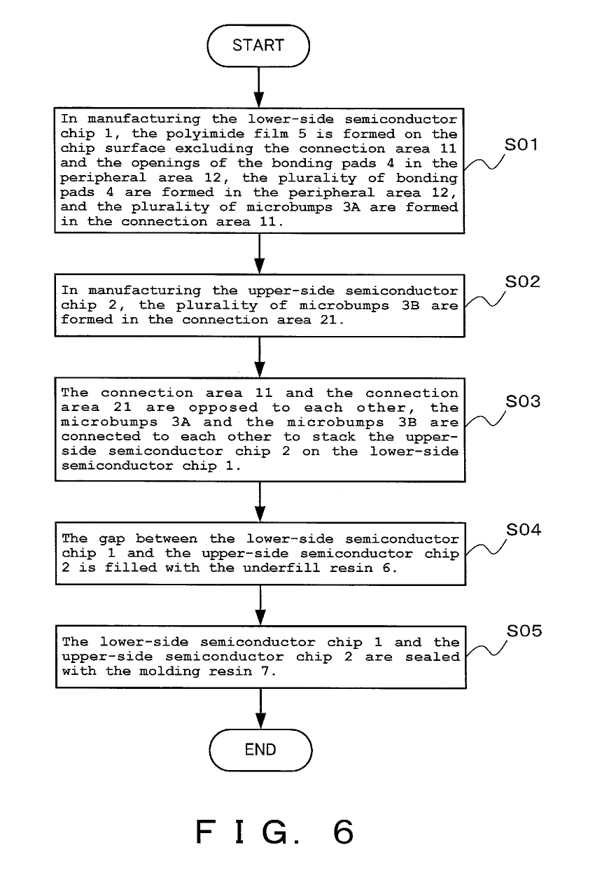

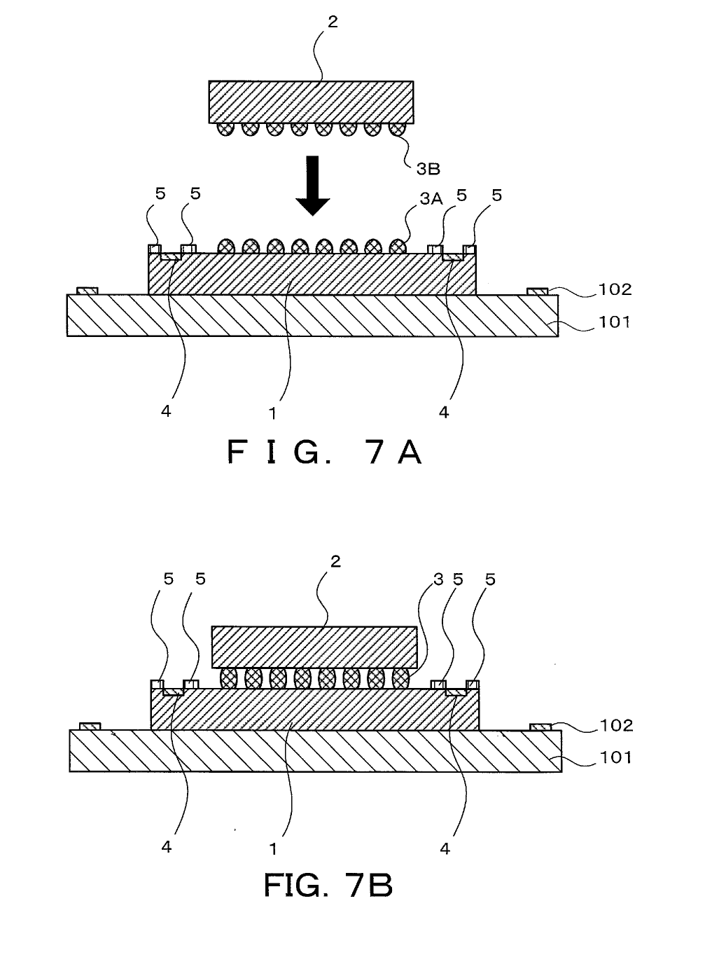

Next, a method for manufacturing the stacked semiconductor device of the embodiment will be described with reference to a flowchart of FIG. 6 and schematic sectional views of FIGS. 7 to 9.

FIG. 6 is a flowchart showing an example of the method for manufacturing the stacked semiconductor device according to the first embodiment of the invention.

In manufacturing the stacked semiconductor device of the embodiment, first, the lower-side semiconductor chip 1 is manufactured. In manufacturing the lower-side semiconductor chip 1, the polyimide film 5 having a film thickness of about 3 μm is formed on the chip surface in the area excluding the connection area 11 and the openings of the bonding pads 4 in the peripheral area 12, the plurality of bonding pads 4 are formed in the peripheral area 12, and the plurality of microbumps 3A are formed in the connection area 11 (Step S01).

At this time, for example, the polyimide film 5 is formed by such a method that photosensitive polyimide is applied on the whole chip surface, and after exposure and development thereof, polyimide in the connection area 11 and at openings of the bonding pads 4 in the peripheral area 12 are removed by etching.

Next, the upper-side semiconductor chip 2 is manufactured. In manufacturing the upper-side semiconductor chip 2, the plurality of microbumps 3B are formed in the connection area 21 (Step S02).

Step S01 and Step S02 can be concurrently conducted using separate manufacturing lines, or alternatively, Step S02 may be executed in advance of Step S01, and thereby, the upper-side semiconductor chip 2 is manufactured in advance.

Subsequently, after the lower-side semiconductor chip 1 has been connected to the wiring substrate 101, the connection area 11 of the lower-side semiconductor chip 1 and the connection area 21 of the upper-side semiconductor chip 2 are opposed to each other as shown in FIG. 7A, the microbumps 3A and the microbumps 3B are connected to each other as shown in FIG. 7B, to stack the upper-side semiconductor chip 2 on the lower-side semiconductor chip 1 (Step S03).

With this mutual connection of the microbumps, the microbumps 3A and the microbumps 3B are unified, to form the microbumps 3 shown in FIG. 7B.

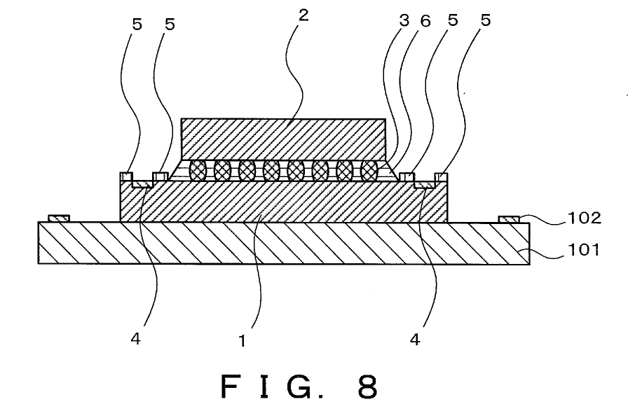

Next, as shown in FIG. 8, the gap between the lower-side semiconductor chip 1 and the upper-side semiconductor chip 2 is filled with the underfill resin 6 (Step S04).

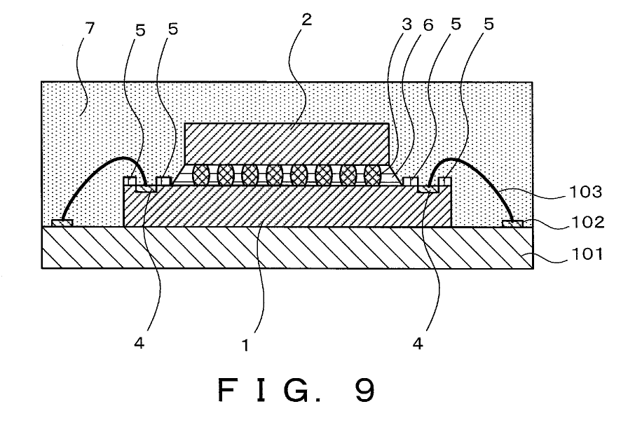

Subsequently, as shown in FIG. 9, after the bonding pad 4 of the lower-side semiconductor chip 1 and the connecting pad 102 of the wiring substrate 101 are connected to each other through the bonding wire 103, the lower-side semiconductor chip 1 and the upper-side semiconductor chip 2 are sealed with the molding resin 7 (Step S05).

With this step, the process for stacking the upper-side semiconductor chip 2 on the lower-side semiconductor chip 1 is completed.

According to the embodiment, since the polyimide film 5 is formed only in the area excluding the openings of the bonding pads 4 in the peripheral area 12 of the lower-side semiconductor chip 1, the molding resin 7 does not come into contact with the chip surface of the lower-side semiconductor chip 1, but comes into contact with the polyimide film 5. Since adhesion between the molding resin 7 and the polyimide film 5 is favorable, thermal stress between the lower-side semiconductor chip 1 and the molding resin 7 can be alleviated, so as to prevent peeling of the molding resin 7 at a chip corner of the lower-side semiconductor chip 1 or the like.

Further, with the polyimide film 5 not formed either in the connection area 11 formed with the microbumps 3A of the lower-side semiconductor chip 1, the gap to fill with the underfill resin 6 is not narrowed, so that non-uniform filling with the underfill resin 6 can be prevented. This can prevent generation of a void in the underfill resin layer.

Further, with the polyimide film 5 not formed in the connection area 11, it is possible to prevent a decrease in measurement accuracy of the gap.

### Second Embodiment

When the gap between the lower-side semiconductor chip 1 and the upper-side semiconductor chip 2 is narrow in the stacked semiconductor device shown in the first embodiment, the higher the flowability of the underfill resin 6, the smaller the number of voids generated in an underfill resin layer can be made. However, when the flowability of the underfill resin 6 is increased, it becomes more possible that the underfill resin 6 outflows to the peripheral area 12 of the lower-side semiconductor chip 1. Therefore, the embodiment shows an example of a stacked semiconductor devices where, even with increase in flowability of the underfill resin 6, the underfill resin 6 does not outflow to the peripheral area 12 of the lower-side semiconductor chip 1.

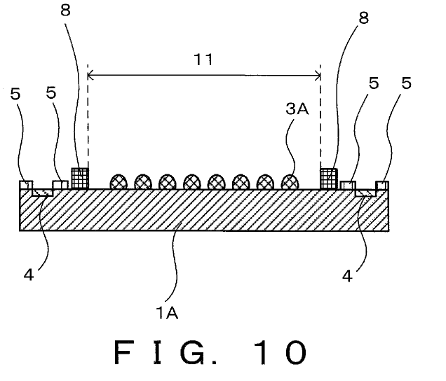

FIG. 10 is a schematic plan view showing a constitutional example of a lower-side semiconductor chip of the stacked semiconductor device according to the second embodiment of the invention.

A lower-side semiconductor chip 1A of the embodiment differs from the lower-side semiconductor chip 1 of the first embodiment in that a dam 8 is provided on the outside of the connection area 11 formed with microbumps 3A for the purpose of preventing outflow of the underfill resin 6. The material for the dam 8 is metal such as silver (Ag), tin (Sn) or an alloy of those (Ag—Sn based solder). Further, in the embodiment, the polyimide film 5 is formed on the outside of the dam 8.

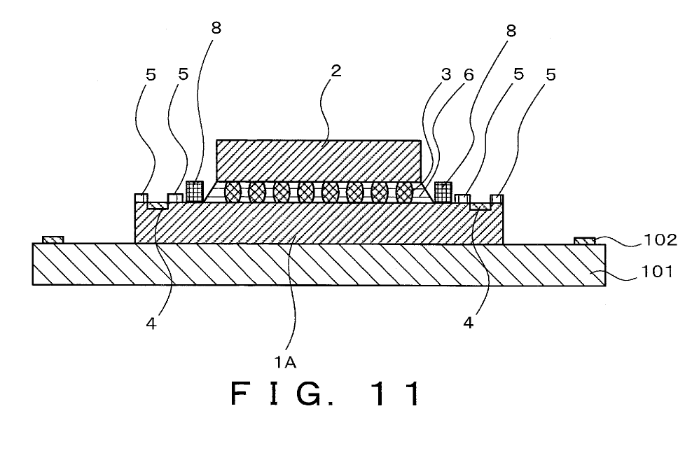

FIG. 11 shows a state where the upper-side semiconductor chip 2 is stacked on the lower-side semiconductor chip 1A of the embodiment, and a gap therebetween is filled with the underfill resin 6.

As shown in FIG. 11, even with use of the underfill resin 6 having high flowability, the dam 8 prevents outflow of the underfill resin 6 to the periphery.

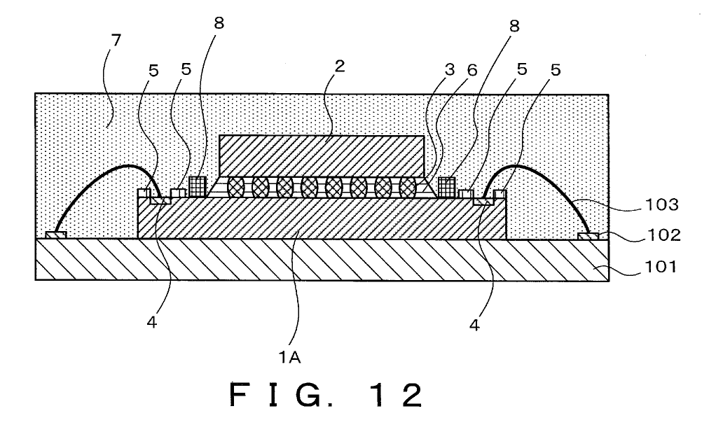

FIG. 12 is a schematic sectional view of the stacked semiconductor device of the embodiment after completion of the process for sealing with the molding resin 7.

Also in the embodiment, since the chip surface of the lower-side semiconductor chip 1 does not come into direct contact with the molding resin 7, it is possible to prevent peeling of the molding resin 7 at a chip corner of the lower-side semiconductor chip 1 or the like. Similarly to the first embodiment, it is possible to suppress generation of a void in the underfill resin layer, so as to prevent a decrease in measurement accuracy of the gap.

Moreover, according to the embodiment, even with the underfill resin 6 having high flowability, it is possible to prevent outflow of the underfill resin 6 to the peripheral area 12 of the lower-side semiconductor chip 1.

Although the example of using polyimide as the material for a film having favorable adhesion to the molding resin is used in each of the above embodiments, the material for the film is not restricted to polyimide, but benzocyclobutene (BCB), polybenzoxazole (PBO), a phenolic resin, or the like may also be used.

According to the invention, it is possible to suppress generation of a void in an underfill resin layer and prevent a decrease in measurement accuracy of a gap between stacked semiconductor chips, while preventing peeling of a molding resin.

What is claimed is:

1. A stacked semiconductor device comprising:
a first semiconductor chip that has a first connection area formed with a first plurality of microbumps and a peripheral area formed with a plurality of bonding pads;
a second semiconductor chip that has a second connection area formed with a second plurality of microbumps on a surface opposed to the first connection area, and is stacked on the first semiconductor chip with the first plurality of microbumps and the second plurality of microbumps connected to each other;
an underfill resin filled in a gap between the first semiconductor chip and the second semiconductor chip;
a molding resin sealing the first semiconductor chip and the second semiconductor chip; and
a film that has favorable adhesion to the molding resin formed on the chip surface in a region excluding openings of the bonding pads out of the peripheral area of the first semiconductor chip.

2. The stacked semiconductor device according to claim 1, wherein a dam for preventing an outflow of the underfill resin is provided on the outside of the first connection area of the first semiconductor chip.

3. The stacked semiconductor device according to claim 1, wherein the film having favorable adhesion to the molding resin is formed in an area on the outside of the area formed with the dam.

4. The stacked semiconductor device according to claim 1, wherein the film having favorable adhesion to the molding resin is any of polyimide, benzocyclobutene (BCB), polybenzoxazole (PBO), and a phenolic resin.

5. The stacked semiconductor device according to claim 1, wherein the film having favorable adhesion to the molding resin is formed in an area on the outside of the bonding pads out of the peripheral area of the first semiconductor chip.

6. The stacked semiconductor device according to claim 1, wherein the film having favorable adhesion to the molding resin is formed at least in corner sections of the peripheral area of the first semiconductor chip.

7. A method for manufacturing a stacked semiconductor device comprising the steps of:
forming a first plurality of microbumps in a first connection area, forming a plurality of bonding pads in a peripheral area, and forming a film with favorable adhesion to a molding resin on the chip surface in the peripheral region excluding openings of the bonding pads of a first semiconductor chip;
forming a second plurality of microbumps in a second connection area of a second semiconductor chip;
stacking the second semiconductor chip on the first semiconductor chip by making the first connection area and the second connection area opposed to each other and connecting the first plurality of microbumps with the second plurality of microbumps;
filling a gap between the first semiconductor chip and the second semiconductor chip with an underfill resin; and
sealing the first semiconductor chip and the second semiconductor chip with the molding resin.

8. A method for manufacturing a stacked semiconductor device according to claim 7, wherein a dam for preventing an outflow of the underfill resin is provided on the outside of the first connection area of the first semiconductor chip.

9. The stacked semiconductor device according to claim 7, wherein the film having favorable adhesion to the molding resin is formed in an area on the outside of the area formed with the dam.

10. A method for manufacturing a stacked semiconductor device according to claim 7, wherein the film having favorable adhesion to the molding resin is any of polyimide, benzocyclobutene (BCB) polybenzoxazole (PBO), and a phenolic resin.

11. A method for manufacturing a stacked semiconductor device according to claim 7, wherein the film having favorable adhesion to the molding resin is formed in an area on the outside of the bonding pads out of the peripheral area of the first semiconductor chip.

12. A method for manufacturing a stacked semiconductor device according to claim 7, wherein the film having favorable adhesion to the molding resin is formed at least in corner sections of the peripheral area of the first semiconductor chip.
